(19) United States
(12) Patent Application Publication
(10) Pub. No.: US 2025/0327844 A1
(43) Pub. Date: Oct. 23, 2025

(54) DETERMINATION OF AN ACTUAL PHASE SHIFT OF A PHASE SHIFTER

(71) Applicant: Infineon Technologies AG, Neubiberg (DE)

(72) Inventor: Dominik HUBER, München (DE)

(21) Appl. No.: 18/643,676

(22) Filed: Apr. 23, 2024

(51) Int. Cl. G01R 25/00

(52) U.S. Cl. CPC G01R 25/00

(57) ABSTRACT

A controller may receive first measurement signals associated with n phase settings of a first phase shifter and while a phase setting of a second phase shifter is a first phase setting of k phase settings. The controller may receive second measurement signals associated with the n phase settings of the first phase shifter and while the phase setting of the second phase shifter is a second phase setting of the k phase settings. The controller may determine n phase difference values based on the first measurement signals and the second measurement signals. The controller may determine two or more actual phase shifts of the second phase shifter based on a weighted average value of the n phase difference values.

### BACKGROUND

A radar device, such as a radar monolithic microwave integrated circuit (MMIC) may use a phase shifter to control a phase of a radio frequency (RF) signal transmitted by the radar device. In general, a phase shifter is a component that adjusts a phase of an input signal without changing a frequency of the signal. The shift applied by the phase shifter can be controlled by, for example, a controller. Phase control is important in an application in which precise timing and phase control are needed. For example, phase control is important in a radar application, which requires precise phase control to ensure that radar-related tasks, such as beam steering, signal processing, interference cancellation, or the like, are performed with acceptable reliability and accuracy.

### SUMMARY

In some implementations, a method includes receiving first measurement signals, wherein the first measurement signals are associated with n phase settings of a first phase shifter, and wherein the first measurement signals are received while a phase setting of a second phase shifter is a first phase setting of k phase settings of the second phase shifter; receiving second measurement signals, wherein the second measurement signals are associated with the n phase settings of the first phase shifter, and wherein the second measurement signals are received while the phase setting of the second phase shifter is a second phase setting of the k phase settings of the second phase shifter; determining n phase difference values based on the first measurement signals and the second measurement signals, wherein the n phase difference values are associated with a difference between the first phase setting of the second phase shifter and the second phase setting of the second phase shifter; and determining two or more actual phase shifts of the second phase shifter based on a weighted average value of the n phase difference values.

In some implementations, a device includes a set of components comprising a first phase shifter and a second phase shifter, the set of components being configured to: provide first measurement signals, wherein the first measurement signals are associated with n phase settings of the first phase shifter, and wherein the first measurement signals are provided while a phase setting of a second phase shifter is at a first phase setting of k phase settings of the second phase shifter; provide second measurement signals, wherein the second measurement signals are associated with the n phase settings of the first phase shifter, and wherein the second measurement signals are provided while the phase setting of the second phase shifter is at a second phase setting of the k phase settings of the second phase shifter; and a controller configured to: receive the first measurement signals; receive the second measurement signals; determine n phase difference values based on the first measurement signals and the second measurement signals, wherein the n phase difference values are associated with a difference between the first phase setting of the second phase shifter and the second phase setting of the second phase shifter; and determine two or more actual phase shifts of the second phase shifter based on the n phase difference values.

In some implementations, a device includes a local oscillator (LO) configured to provide an LO signal; a transmit phase shifter (TXPS) configured to phase shift transmit signals according to n phase settings of the TXPS, wherein the transmit signals are based on the LO signal; a test phase shifter (TPS) configured to phase shift test signals according to k phase settings of the TPS, wherein the test signals are based on the LO signal; a mixer configured to generate mixed signals based on the transmit signals and the test signals; an analog to digital converter (ADC) configured to digitize the mixed signals to generate measurement signals; and a controller configured to: determine n phase difference values based on the measurement signals, wherein the n phase difference values are associated with a difference between a first phase setting of the k phase settings of the TPS and a second phase setting of the k phase settings of the TPS; and determine two or more actual phase shifts of the TPS based on the n phase difference values.

### BRIEF DESCRIPTION OF THE DRAWINGS

FIGS. 1A-1E are diagrams associated with an example implementation of a device capable of determining an actual phase of a phase shifter, as described herein.

FIG. 2 is a diagram illustrating another example implementation of a device capable of determining an actual phase of a phase shifter, as described herein.

FIG. 3 is a diagram of example components of a device associated with determination of an actual phase shift of a phase shifter.

FIG. 4 is a flowchart of an example process associated with determination of an actual phase shift of a phase shifter.

### DETAILED DESCRIPTION

The following detailed description of example implementations refers to the accompanying drawings. The same reference numbers in different drawings may identify the same or similar elements.

As described above, a phase shifter may be used to control or adjust a phase of an RF signal for which precise phase control is important. As one example, a phase shifter may be used to control or adjust a phase of a transmit (TX) RF signal, provided by a radar device (e.g., a radar MMIC), for which precise phase control is needed in association with performing radar-related tasks such as beam steering, signal processing, or interference cancellation, among other examples. Characterization of a phase shifter used in such an application is important to ensure reliable and accurate operation of the radar device. The term “characterization,” as used herein, refers to knowledge of actual phase shifts that are applied by the phase shifter relative to, for example, phase shifts that are intended to be applied by the phase shifter.

One conventional technique to characterize a TX phase shifter (TXPS) in a radar device uses a test phase shifter (TPS). This technique relies on an accurate characterization of the TPS (i.e., prior knowledge about actual phases of the TPS). One implementation of the conventional technique uses an 8-bin fast Fourier transform (FFT) that relies on phase settings of the TPS (0 degrees (°), 45°, 90°, 135°, 180°, 225°, 270°, 315°). Notably, this implementation requires that a gain and an offset be the same for all phase settings of the TPS. One disadvantage of this implementation is that knowledge of actual phases associated with each TPS setting is needed, which requires tight manufacturing tolerances or expensive characterization of the TPS by external measurements. As a result, a cost of such a radar device that uses the conventional technique for characterization of the TXPS is increased. Further, phase measurement errors in radar devices in which this conventional technique is implemented may in some cases still be unacceptably high for some applications.

Some implementations described herein provide techniques and apparatuses for determination of an actual phase shift of a phase shifter. In some implementations, a controller (e.g., of a radar device) may receive first measurement signals that are associated with n (n is an integer greater than 1) phase settings of a first phase shifter (e.g., a TXPS). The first measurement signals are received while a phase setting of a second phase shifter (e.g., a TPS) is a first phase setting of k (k is an integer greater than 1) phase settings of the second phase shifter. The controller may further receive second measurement signals associated with the n phase settings of the first phase shifter. The second measurement signals are received while the phase setting of the second phase shifter is a second phase setting of the k phase settings of the second phase shifter. The controller may then determine n phase difference values based on the first measurement signals and the second measurement signals, with the n phase difference values being associated with a difference between the first phase setting of the second phase shifter and the second phase setting of the second phase shifter. The controller may then determine two or more actual phase shifts of the second phase shifter based on a weighted average value of the n phase difference values.

Notably, the techniques and apparatuses described herein do not require prior knowledge of actual phases associated with phase settings of a TPS, while enabling measurement of a differential phase of a TX signal, and therefore an actual phase of the TXPS. Further, the techniques and apparatuses described herein reduce phase errors (e.g., as compared to the conventional technique above). Therefore, the techniques and apparatuses described herein can reduce a cost associated with a radar device (e.g., due to relaxed manufacturing tolerances or elimination of a need to characterize the TXPS and/or TPS using external measurements) while improving performance. Further, the techniques and apparatuses described herein may require fewer measurement data points than the conventional FFT-based technique, meaning that a data acquisition time for a given phase measurement is reduced. Additional details are provided below.

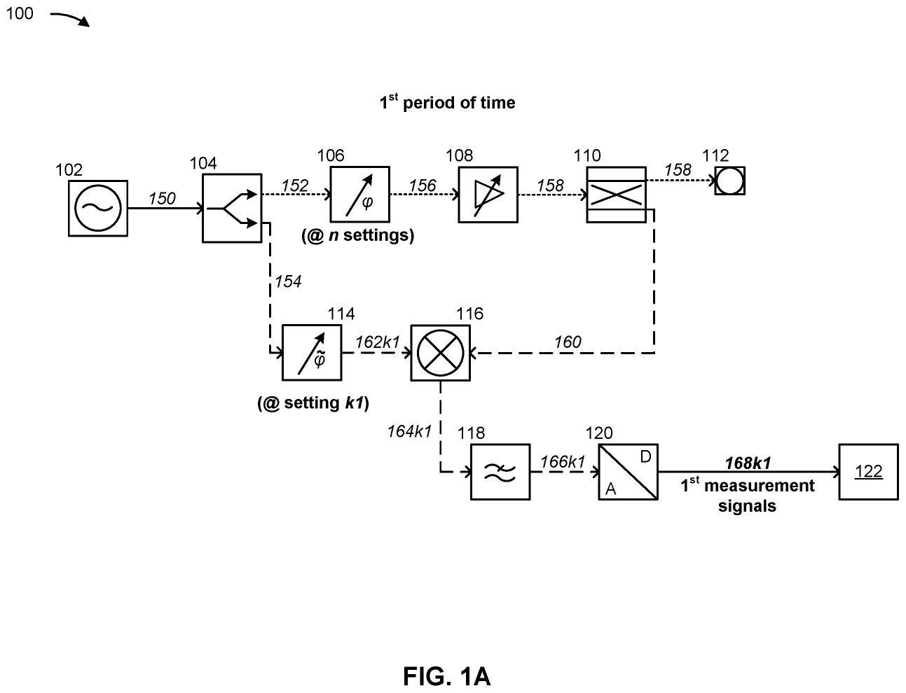

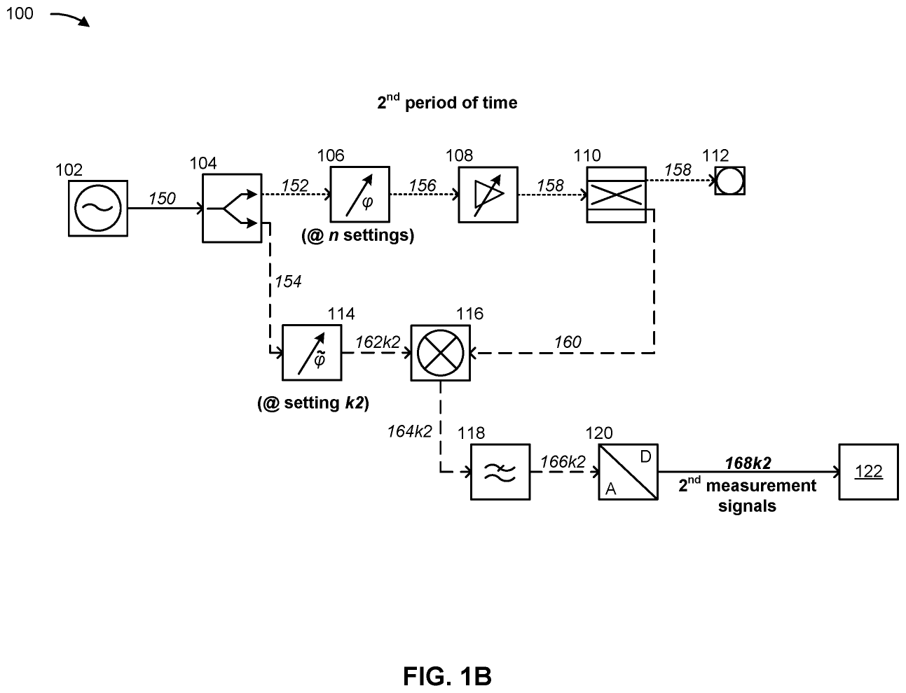

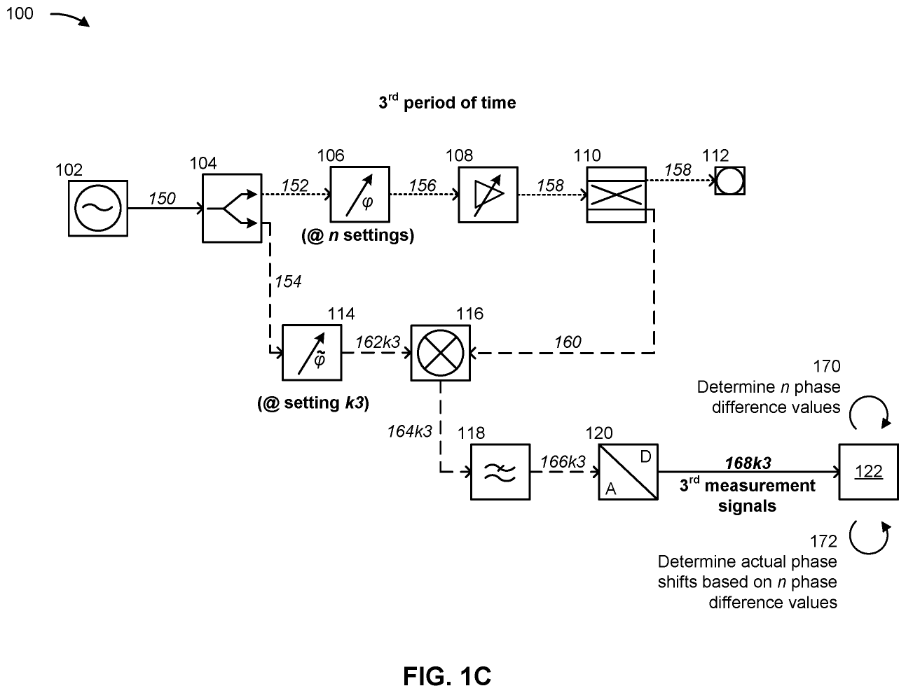

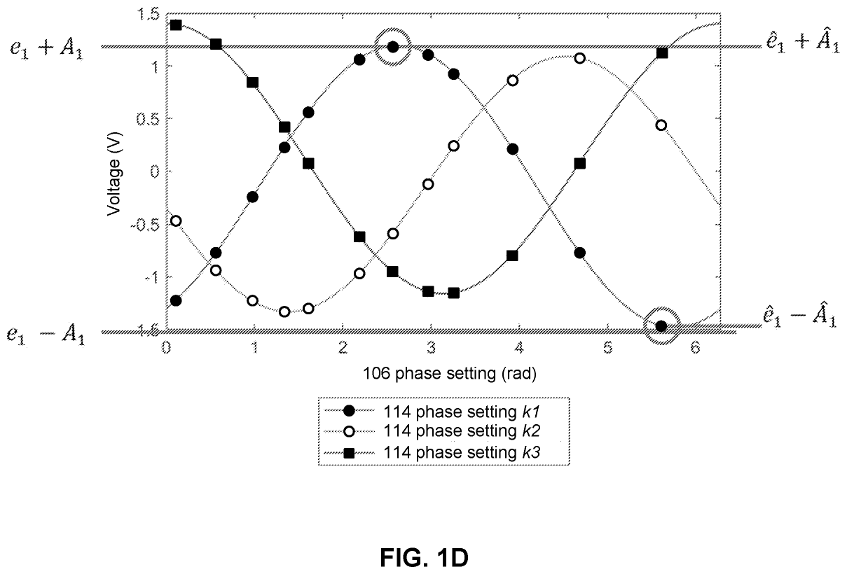

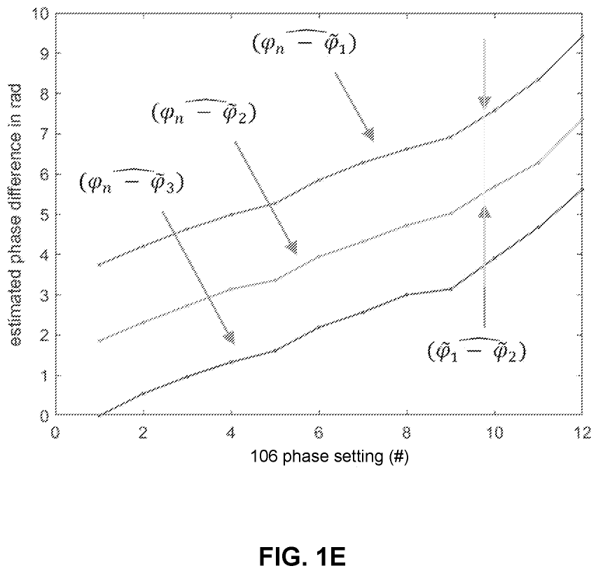

FIGS. 1A-1E are diagrams associated with an example implementation of a device 100 capable of determining an actual phase of a phase shifter, as described herein. As shown in FIGS. 1A-1C, the device 100 may include a local oscillator (LO) 102, a splitter 104, a first phase shifter 106 (e.g., a TXPS), a power amplifier (PA) 108, a coupler 110, a TX output 112, a second phase shifter 114 (e.g., a TPS), a mixer 116, a low pass filter (LPF) 118, an analog-to-digital converter (ADC) 120, and a controller 122. In some implementations, the device 100 may be included in, for example, a radar device (e.g., a radar MMIC). Details of the components of the device 100 are described below, followed by an example description of operation of the device 100.

The LO 102 is a component configured to provide an RF oscillator signal (herein referred to as an LO signal 150). In some implementations, the LO signal 150 may be in a super high frequency (SHF) band (e.g., centimeter wave) or in an extremely high frequency (EHF) band (e.g., millimeter wave), for example, in a range between approximately 76 gigahertz (GHz) and approximately 81 GHz. In some radar applications, the LO signal 150 may be in a 24 GHz industrial, scientific, and medical (ISM) band. The LO signal 150 may also be generated at a lower frequency and then up-converted using frequency multiplication units. In some implementations, the LO signal 150 is processed both in a TX RF signal path (shown using dotted lines in FIGS. 1A-1C) of a TX channel and in a received RF signal path (not shown) of a receive (RX) channel. As shown in FIG. 1, the LO 102 may be configured to provide the LO signal 150 to the splitter 104.

The splitter 104 is a component to split the LO signal (i.e., the RF input to the splitter 104) to create one or more output RF signals. For example, in the example implementation of the device 100 shown in FIGS. 1A-1C, the splitter 104 is a component that splits the LO signal 150 to create a TX RF input signal 152 that is provided to the first phase shifter 106 and a TX test signal 154 that is provided to the second phase shifter 114. As shown, the TX RF input signal 152 is provided on the TX RF signal path of the device 100, while the TX test signal 154 is provided on a monitoring signal path of the device 100 (shown using dashed lines in FIGS. 1A-1C).

The first phase shifter 106 is a component that is to phase shift TX signals of the device 100 according to n (n>1) phase settings of the first phase shifter 106. More particularly, the first phase shifter 106 is a component that is to apply phase shifts to the TX RF input signal 152 to create a phase shifted TX RF signal 156. In some implementations, the first phase shifter 106 may be referred to as a TXPS. In some implementations, the first phase shifter 106 has n phase settings, with each of the n phase settings being in the range from 0° to 360°. Thus, at a given time, the first phase shifter 106 may apply any one of n different phase shifts to the TX RF input signal 152. Here, a desired phase shift that is to be applied by the first phase shifter 106 at a given time may be selectable, configurable, or otherwise adjustable (e.g., based on a control signal provided to the first phase shifter 106). In some implementations, the phase setting applied by the first phase shifter 106 may change in association with generating measurement signals (e.g., such that each of the n phase settings is applied by the first phase shifter 106 to generate the measurement signals). For example, with respect to FIG. 1A, the phase setting applied by the first phase shifter 106 may change over a first period of time such that each of the n phase settings is applied by the first phase shifter 106 in association with generating first measurement signals 168k1. As another example, with respect to FIG. 1B, the phase setting applied by the first phase shifter 106 may change over a second period of time such that each of the n phase settings is applied by the first phase shifter 106 in association with generating second measurement signals 168k2. As another example, with respect to FIG. 1C, the phase setting applied by the first phase shifter 106 may change over a third period of time such that each of the n phase settings is applied by the first phase shifter 106 in association with generating third measurement signals 168k3. Notably, in the above examples, the measurement signals 168k1, the measurement signals 168k2, and the measurement signals 168k3 are generated in a sequential manner. However, the measurement signals 168k1, the measurement signals 168k2, and the measurement signals 168k3 can in some implementations be generated in another manner, such as a parallelized manner, as described below with respect to the example of operation of the device 100.

In some implementations, the n phase settings of the first phase shifter 106 may be (monotonically) incremented (e.g., such that an increment between a given phase setting and a next closest phase setting may be less than approximately 60°). In such a case, an increment from a highest phase setting to a lowest phase setting may also be less than approximately 60° when 360° is subtracted from the highest phase setting. Put another way, in some implementations, an increment between a given phase setting of the n phase settings and a next phase setting in a sequence of the n phase settings when ordered by ascending phase setting values may be less than approximately 60°. In the example implementation of the device 100 shown in FIGS. 1A-1C, the phase shifted TX RF signal 156 created by the first phase shifter 106 is provided to the PA 108.

The PA 108 is a component that is to amplify the phase shifted TX RF signal 156 to create an amplified phase shifted TX RF signal 158. That is, the PA 108 is a component that is to increase a power level of an output of the first phase shifter 106 on the TX RF signal path. In the example implementation of the device 100 shown in FIGS. 1A-1C, the amplified phase shifted TX RF signal 158 created by the PA 108 is provided to the coupler 110.

The coupler 110 is a component (e.g., a directional coupler) that is to couple a portion of the amplified phase shifted TX RF signal 158 (e.g., a predefined amount of power in a transmission line of the amplified phase shifted TX RF signal 158) to the monitoring signal path of the device 100. Here, the portion of the amplified phase shifted TX RF signal 158 that is coupled to the monitoring signal path is identified as a TX monitoring signal 160. As shown, the remaining portion of the amplified phase shifted TX RF signal 158 is provided as the TX output 112 (e.g., such that the remaining portion of the amplified phase shifted TX RF signal 158 is transmitted by the device 100).

The second phase shifter 114 is a component that is to phase shift test signals of the device 100 according to k (k>1) phase settings of the first phase shifter 106. More particularly, the second phase shifter 114 is a component that is to apply phase shifts to the TX test signal 154 to create a phase shifted TX test signal 154. In some implementations, the second phase shifter 114 may be referred to as a TPS. In some implementations, the second phase shifter 114 has k (k>1) phase settings, with each of the k phase settings being in the range from 0° to 360°. Thus, at a given time, the second phase shifter 114 is capable of applying any one of k different phase shifts to the TX test signal 154. Here, a desired phase shift that is to be applied by the second phase shifter 114 at a given time may be selectable, configurable, or otherwise adjustable (e.g., based on a control signal provided to the second phase shifter 114).

In some implementations, the phase setting to be applied by the second phase shifter 114 may be selected in association with generating measurement signals. For example, with respect to FIG. 1A and in association with generating first measurement signals 168k1, the phase setting applied by the second phase shifter 114 may be a first phase setting k1, of the k phase settings, during a first period of time over which the phase setting applied by the first phase shifter 106 is changed such that each of the n phase settings is applied by the first phase shifter 106. Continuing with this example, with respect to FIG. 1B and in association with generating second measurement signals 168k2, the phase setting applied by the second phase shifter 114 may be a second phase setting k2, of the k phase settings, during a second period of time over which the phase setting applied by the first phase shifter 106 is changed such that each of the n phase settings is applied by the first phase shifter 106. Continuing with this example, with respect to FIG. 1C and in association with generating third measurement signals 168k3, the phase setting applied by the second phase shifter 114 may be a third phase setting k3, of the k phase settings, during a third period of time over which the phase setting applied by the first phase shifter 106 is changed such that each of the n phase settings is applied by the first phase shifter 106. Notably, in the above examples, the measurement signals 168k1, the measurement signals 168k2, and the measurement signals 168k3 are generated in a sequential manner. However, the measurement signals 168k1, the measurement signals 168k2, and the measurement signals 168k3 can in some implementations be generated in another manner, such as a parallelized manner, as described below with respect to the example of operation of the device 100.

In some implementations, the second phase shifter 114 has two phase settings (e.g., k=2). In some such implementations, the first phase shifter 106 may have at least five phase settings (e.g., n≥5 when k=2). In some implementations, the second phase shifter 114 has at least three phase settings (e.g., k≥3). In such an implementation, the first phase shifter 106 may have at least four phase settings (e.g., n≥4 when k≥3). In the example implementation of the device 100 shown in FIGS. 1A-1C, a phase shifted TX test signal 162 created by the second phase shifter 114 during a given period of time (e.g., a phase shifted TX test signal 162k1 created during the first period of time, a phase shifted TX test signal 162k2 created during the second period of time) is provided to the mixer 116.

The mixer 116 is a component that is to mix the TX monitoring signal 160 provided by the coupler 110 with the phase shifted TX test signal 162 provided by the second phase shifter 114 to generate a TX phase monitoring signal 164 (e.g., TX phase monitoring signal 164k1 during the first period of time, a TX phase monitoring signal 164k2 during the second period of time, a TX phase monitoring signal 164k3 during the third period of time, or the like). More generally, the mixer 116 is a component configured to generate mixed signals based on TX signals (e.g., provided by the coupler 110) and test signals (e.g., provided by the second phase shifter 114). In the example implementation of the device 100 shown in FIGS. 1A-1C, the TX phase monitoring signal 164 created by the mixer 116 is provided to the LPF 118.

The LPF 118 is a component that is to filter the TX phase monitoring signal 164 provided by the mixer to create a filtered TX phase monitoring signal 166 (e.g., filtered TX phase monitoring signal 166k1, filtered TX phase monitoring signal 166k2, filtered TX phase monitoring signal 166k3, or the like). In some implementations, the LPF 118 serves to remove unwanted higher frequency noise or harmonics generated by one or more components of the device 100 (e.g., so as to maintain signal purity). In the example implementation of the device 100 shown in FIGS. 1A-1C, the filtered phase monitoring signal created by the LPF 118 is provided to the ADC 120.

The ADC 120 is a component to convert analog signals to digital signals. More particularly, the ADC 120 is a component configured to digitize the filtered phase monitoring signal 166 provided by the LPF 118 to create a measurement signal 168 (e.g., measurement signal 168k1 during the first period of time, a measurement signal 168k2 during the second period of time, or the like). That is, the ADC 120 may be a component configured to digitize a direct current (DC) component of a (filtered) product of the mixing of the TX monitoring signal 160 and the phase shifted TX test signal 162. Thus, in some implementations, measurement signals 168 are a digitized version of a DC component of a result of mixing a TX signal (e.g., represented by the TX monitoring signal 160) and a phase-shifted test signal (e.g., the phase shifted TX test signal 162), with the TX signal and the phase-shifted test signal originating from the LO 102.

In the example implementation of the device 100, the measurement signal 168 (e.g., the measurement signal 168k1 during the first period of time, the measurement signal 168k2 during the second period of time) generated by the ADC 120 is provided to the controller 122.

The controller 122 is a component associated with controlling or monitoring operation of the device 100. In some implementations, the controller 122 may be configured to monitor and/or control phases applied by the first phase shifter 106 and/or the second phase shifter 114 so as to provide phase compensation or phase correction for the device 100. In some implementations, the controller may be configured to determine actual phase shifts of the second phase shifter 114 and/or of the first phase shifter 106 (e.g., based on measurement signals 168 received from the ADC 120), and provide phase correction based on the actual phase shifts.

In practice, a signal received at the controller 122 (e.g., the signal provided by the ADC 120) may be a voltage signal. Thus, the voltage at the ADC results in a measurement signal 168 that may be represented by the following equation:

$${y}_{k} ( φ ) = {A}_{k} cos ( φ - {\tilde{φ}}_{k} ) + {e}_{k}$$

where φ represents an actual phase shift of the first phase shifter 106, \tilde{φ}ₖ, k∈{1, . . . , K} represents an actual phase shift of the second phase shifter 114, and the parameters Aₖ and eₖ represent the gain and DC offset, respectively, associated with a given phase setting of the k phase settings of the second phase shifter 114. For simplicity, phases of the PA 108 and other components of the device 100 can be considered to be included in the actual phase shift p of the first phase shifter 106. The phase shift p of the first phase shifter 106 is realized in N different instances. Assumptions used in association with techniques described below are that the phase shifts φₙ, n∈{1, . . . , N} are (monotonically) increasing, as described above. Available data samples at the controller 122 as provided by measurement signals 168 may be represented by the following equation:

$${y}_{kn} = {A}_{k} cos ( {φ}_{n} - {\tilde{φ}}_{k} ) + {e}_{k}$$

In some implementations, the controller 122 may be configured to determine the actual phase shifts \tilde{φ}ₖ of the second phase shifter 114 and/or the actual phase shifts φₙ of the first phase shifter 106 from the available data set Y=(yₖₙ), as described below.

In an example operation of the device 100, with reference to FIG. 1A, the controller 122 receives first measurement signals 168k1. Here, the first measurement signals 168k1 are associated with the n phase settings of the first phase shifter 106, meaning that the first phase shifter 106 (separately) applies each of the n phase settings within a first period of time. Further, during the first period of time, the phase setting of the second phase shifter 114 is kept at a first phase setting k1 of the k phase settings of the second phase shifter 114. Thus, the first measurement signals 168k1 comprise a first set of n digital values, where each digital value in the first set of n digital values corresponds to a DC component of a result of mixing the TX monitoring signal 160 and the phase shifted test signal 162k1, with the TX monitoring signal 160 being phase-shifted by the first phase shifter 106 by a respective phase setting of the n phase settings while the second phase shifter 114 is set to the first phase setting k1 of the k phase settings. Similarly, with reference to FIG. 1B, the controller 122 receives second measurement signals 168k2. The second measurement signals 168k2 are associated with the n phase settings of the first phase shifter 106, meaning that the first phase shifter 106 (separately) applies each of the n phase settings within a second period of time. Further, during the second period of time, the phase setting of the second phase shifter 114 is kept at a second phase setting k2 of the k phase settings of the second phase shifter 114. Thus, the second measurement signals 168k2 comprise a second set of n digital values, where each digital value in the second set of n digital values corresponds to a DC component of a result of mixing the TX monitoring signal 160 and the phase shifted test signal 162k2, while the TX monitoring signal is phase-shifted by the first phase shifter 106 by a respective phase setting of the n phase settings and the second phase shifter 114 is set to the second phase setting k2 of the k phase settings. Similarly, with reference to FIG. 1C, the controller 122 receives third measurement signals 168k3. The third measurement signals 168k3 are associated with the n phase settings of the first phase shifter 106, meaning that the first phase shifter 106 (separately) applies each of the n phase settings within a third period of time. Further, during the third period of time, the phase setting of the second phase shifter 114 is kept at a third phase setting k3 of the k phase settings of the second phase shifter 114. Thus, the third measurement signals 168k3 comprise a third set of n digital values, where each digital value in the third set of n digital values corresponds to a DC component of a result of mixing the TX monitoring signal 160 and the phase shifted test signal 162k3, while the TX monitoring signal is phase-shifted by the first phase shifter 106 by a respective phase setting of the n phase settings and the second phase shifter 114 is set to the third phase setting k3 of the k phase settings. The controller 122 may obtain additional measurement signals in a similar manner (e.g., the controller 122 may receive k measurement signals 168, each associated with a different one of the k phase settings of the second phase shifter 114).

Notably, in the example operation described above, the measurement signals 168k1, the measurement signals 168k2, and the measurement signals 168k3 are generated in a sequential manner (e.g., such that the first measurement signals 168k1 are generated in a period of time during which the second phase shifter 114 applies the first phase setting k1, the second measurement signals 168k2 are generated in a period of time during which the second phase shifter 114 applies the second phase setting k2, and the third measurement signals 168k3 are generated in a period of time during which the second phase shifter 114 applies the third phase setting k3). However, the measurement signals 168k1, the measurement signals 168k2, and the measurement signals 168k3 can in some implementations be generated in another manner, such as a parallelized manner. For example, the phase setting applied by the first phase shifter 106 may be a first phase setting n1, of the n phase settings, during a first period of time over which the phase setting applied by the second phase shifter 114 is changed such that each of the k phase settings is applied by the second phase shifter 114. Continuing with this example, the phase setting applied by the first phase shifter 106 may be a second phase setting n2, of the n phase settings, during a second period of time over which the phase setting applied by the second phase shifter 114 is changed such that each of the k phase settings is applied by the second phase shifter 114. Continuing with this example, the phase setting applied by the first phase shifter 106 may be a second phase setting n3, of the n phase settings, during a third period of time over which the phase setting applied by the second phase shifter 114 is changed such that each of the k phase settings is applied by the second phase shifter 114. The first phase shifter 106 and the second phase shifter 114 may continue operation in this manner such that the first phase shifter 106 applies each of the n phase settings during a respective period of time. In this way, the device 100 may operate to generate measurement signals 168 (e.g., the first measurement signals 168k1, the second measurement signals 168k2, the third measurement signals 168k3, or the like) in a parallelized manner. In general, the first phase shifter 106 and the second phase shifter 114 may be configured in any manner that enables measurement signals 168 associated with each of the k phase settings to be generated such that a matrix of n×k values is provided, where each of the n rows (or columns) of the matrix corresponds to one of the n phase settings of the first phase shifter 106 and each of the k columns (or rows) of the matrix corresponds to one of the k phase settings of the second phase shifter 114.

In this way, the controller 122 may obtain K*N samples yₖₙ (yₖₙ=Aₖ cos(φₙ−\tilde{φ}ₖ)+eₖ) based on which to evaluate phases of the second phase shifter 114 and/or the first phase shifter 106. FIG. 1D is a diagram illustrating an example of the yₖₙ samples obtained by the controller 122 when the first phase shifter 106 has 12 phase settings (n=12) and the second phase shifter 114 has three phase settings (k=3). As indicated in FIG. 1D, data points on a given line are a respective one of the k phase settings of the second phase shifter 114.

Returning to FIG. 1C, as shown at reference 170, the controller 122 may determine n phase difference values based on the first measurement signals 168k1 and the second measurement signals 168k2 (e.g., based on the yₖₙ samples). Here, the n phase difference values are associated with a difference between a given one of the k phase settings and another phase setting of the k phase settings (e.g., a first set of n difference values may be associated with a difference between the first phase setting k1 of the second phase shifter 114 and the second phase setting k2 of the second phase shifter 114). In some implementations, to determine the n phase difference values, the controller 122 may compute a gain value Aₖ and an offset value eₖ for each of the k phase settings. For example, for each k, the controller 122 may select a maximum signal value (e.g., a maximum voltage) and a minimum signal value (e.g., a minimum voltage) from the samples associated with the corresponding measurement signal 168 to obtain estimates for Aₖ and eₖ using equations having the following form:

$${\hat{A}}_{k} = \frac{{max}_{n ∈ \{ 1 , … , N \}} ( {y}_{kn} ) - {min}_{n ∈ \{ 1 , … , N \}} ( {y}_{kn} )}{2}$$

$${\hat{e}}_{k} = \frac{{max}_{n ∈ \{ 1 , … , N \}} ( {y}_{kn} ) + {min}_{n ∈ \{ 1 , … , N \}} ( {y}_{kn} )}{2}$$

As one example, estimates for A₁ and e₁ associated with the first phase setting k1 are indicated by horizontal lines in FIG. 1D.

The controller 122 may then determine phase difference signals based on the estimates for Aₖ and eₖ, along with the k measurement signals 168. In some implementations, a phase difference signal is a signal indicative of differences between the n phase settings of the first phase shifter 106 and a phase setting of the k phase settings of the second phase shifter 114. In some implementations, the controller 122 may determine k phase difference signals, each associated with a respective one of the k phase settings of the second phase shifter 114. In some implementations, to determine the difference signals, the controller 122 may solve yₖₙ (yₖₙ=Aₖ cos(φₙ−\tilde{φ}ₖ)+eₖ) for (φₙ−\tilde{φ}ₖ), with differentiation between a falling side of the cosine (i.e., where φₙ−\tilde{φ}ₖ<π) and a rising side of the cosine (i.e., where φₙ−\tilde{φ}ₖ>π), and may unwrap the resulting phases in the direction of n:

$$( ) = {unwrap}_{n} ( \{ \begin{matrix}arc cos ( \frac{{y}_{kn} - {\hat{e}}_{k}}{{\hat{A}}_{k}} ) & if {y}_{k ( n - 1 )} > {y}_{k ( n + 1 )} \\ 2 π - arc cos ( \frac{{y}_{kn} - {\hat{e}}_{k}}{{\hat{A}}_{k}} ) , & else\end{matrix} )$$

with yₖ₀:=y_{kN} and y_{k(N+1)}:=yₖ₁ to account for a circular shift invariance of the phases. FIG. 1E is a diagram illustrating an example of phase difference signals determined by the controller 122 based on the samples shown in FIG. 1D. In FIG. 1E, each line corresponds to a difference between the n phase settings of the first phase shifter 106 and a respective one of the k phase settings of the second phase shifter 114 (i.e., each line in FIG. 1E corresponds to a different one of the k phase settings of the second phase shifter 114).

The controller 122 may then determine n phase difference values, associated with a given pair of the k phase settings, based on the phase difference signals. For example, the controller 122 may determine n phase difference values based on the first phase difference signal associated with the first phase setting k1 and the second phase difference signal associated with the second phase setting k2. In some implementations, the controller 122 may determine the n phase differences by exploiting the following identity:

$$( {\tilde{φ}}_{k} - {\tilde{φ}}_{m} ) = ( {φ}_{n} - {\tilde{φ}}_{m} ) - ( {φ}_{n} - {\tilde{φ}}_{k} )$$

For example, using this identity, now n different values for (\tilde{φ}ₖ [symbol] \tilde{φ}ₘ) are available. In some implementations, to increase robustness of the result, a weighted average of these values is calculated. For example, in some implementations, a weight cₖₙ can be defined as:

$${c}_{kn} = 1 - {cos}^{2} = 1 - {( \frac{{y}_{kn} - {\hat{e}}_{k}}{{Â}_{k}} )}^{2} ,$$

in order to determine a weighted average of all available (φₙ [symbol] \tilde{φ}ₘ)−(φₙ [symbol] \tilde{φ}ₖ) to get an estimate of the differential phases (\tilde{φ}ₖ [symbol] \tilde{φ}ₘ) associated with the second phase shifter 114:

$$( ) = \frac{{\sum }_{n = 1}^{N} ( ( ) - ( ) ) {c}_{kn} {c}_{mn}}{{\sum }_{n = 1}^{N} {c}_{kn} {c}_{mn}} .$$

In some implementations, the weights cₖₙ are advantageous because the arccos function is comparatively more sensitive near edges (e.g., near −1 and +1) than at a center region (e.g., near 0). The derivative of arccos(x) is

$$\frac{- 1}{\sqrt{1 - {x}^{2}}} ,$$

so weights \sqrt{1−x²} can be used in some implementations. However, the square root function may be costly and may not provide additional benefit and, therefore, 1−x² may be used as weights (without the square root function), where

$$x = \frac{{y}_{kn} - {\hat{e}}_{k}}{{Â}_{k}} .$$

As shown at reference 172, the controller then determines actual phase shifts of the second phase shifter 114 based on a weighted average value of the n phase difference values. For example, from the n phase difference values, the controller 122 may extract the actual phase shifts [symbol] of the second phase shifter 114 using an equally weighted average, and defining that a mean of the phase shifts of the second phase shifter 114 should be zero:

$$= \frac{{\sum }_{m = 1}^{K} ( )}{K} .$$

Here, because only relative phases are relevant, these phase shifts [symbol] can in some cases also be normalized by, for example, defining

$$= 0 :$$

$$= \hat{{\tilde{φ}}_{k}} - \hat{{\tilde{φ}}_{1}}$$

Notably, this normalization step is arbitrary, and provides a constant offset in all resulting phases.

In some implementations, using estimates for the actual phase shifts \tilde{φ}ₖ of the second phase shifter 114, the controller 122 may in some implementations estimate phase shifts φₙ of the first phase shifter 106 with a weighted average using, for example, the weight cₖₙ as described above:

$${\hat{φ}}_{n} = \frac{{\sum }_{k = 1}^{K} ( + \hat{{\tilde{φ}}_{k}} ) {c}_{kn}}{{\sum }_{k = 1}^{K} {c}_{kn}}$$

In this way, the controller 122 may determine k actual phase shifts of the second phase shifter 114, with each actual phase shift of the k actual phase shifts being associated with a respective phase setting of the k phase settings of the second phase shifter 114 and (optionally) may determine n actual phase shifts of the first phase shifter 106, with each actual phase shift of the n actual phase shifts being associated with a respective phase setting of the n phase settings of the first phase shifter 106. In some implementations, as indicated above, the controller 122 may determine the n actual phase shifts of the first phase shifter 106 based on the k actual phase shifts of the second phase shifter 114.

In some implementations, the estimation of the actual phase shifts [symbol] of the second phase shifter 114 determined by the controller 122 and/or of the actual phase shifts \hat{φ}ₙ of the first phase shifter 106 can be improved by one or more of the iteration steps. That is, in some implementations, the controller 122 may perform one or more iterations associated with improving the k actual phase shifts of the second phase shifter 114 or the n actual phase shifts of first phase shifter 106 as determined by the controller 122. For example, the controller 122 in some implementations may compute one or more updated gain values and one or more updated offset values associated with the second phase shifter 114, and may determine updated actual phase shifts of the second phase shifter 114 based on the one or more updated gain values and the one or more updated offset values. In some implementations, to determine the updated gain and offset values, the controller 122 may repurpose the initial estimation step described above, with the following modifications: (1) the controller 122 may improve Âₖ and êₖ from the following equations (rather than the equations noted above with respect to the initial estimation of Âₖ and êₖ)

$${Â}_{k} = \frac{{y}_{{kn}_{k , 1}} - {y}_{{kn}_{k , 2}}}{cos ( {\hat{φ}}_{{n}_{k , 1}}^{( prev )} - {\hat{\tilde{φ}}}_{k}^{( prev )} ) - cos ( {\hat{φ}}_{{n}_{k , 2}}^{( prev )} - {\hat{\tilde{φ}}}_{k}^{( prev )} )} , and$$

$${\hat{e}}_{k} = {y}_{{kn}_{k , 1}} - {Â}_{k} cos ( {\hat{φ}}_{{n}_{k , 1}}^{( prev )} - {\hat{\tilde{φ}}}_{k}^{( prev )} ) ,$$

(with

$${n}_{k , 1} = {arg max}_{n ∈ \{ 1 , … , N \}} ( {y}_{kn} ) and {n}_{k , 2} = {arg min}_{n ∈ \{ 1 , … , N \}} ( {y}_{kn} ) ) ,$$

and (2) the controller 122 may weight samples where

$${max}_{n ∈ \{ 1 , … , N \}} ( {y}_{kn} ) and {min}_{n ∈ \{ 1 , … , N \}} ( {y}_{kn} )$$

are reached with a value of 0. In some implementations, weighting the samples where

$${max}_{n ∈ \{ 1 , … , N \}} ( {y}_{kn} ) and {min}_{n ∈ \{ 1 , … , N \}} ( {y}_{kn} )$$

are reached with a value of zero improves the estimation of Âₖ and êₖ because the controller 122 cannot determine whether the samples are in the decreasing interval of the cosine function or in the increasing interval of the cosine function. Thus, the algorithm could not converge to a non-zero error (without weighting these samples with the value of 0). Consequently, in some such implementations, in association with determining the updated actual phase shifts, the controller 122 may apply a weight value of zero to minimum and maximum values of the measurement signals 168.

An alternative technique that can be used by the controller 122 to perform one or more iterations uses the determined knowledge of \hat{φ}ₙ− [symbol] to improve the estimations of Aₖ and eₖ using the following equations as noted above:

$${\hat{A}}_{k} = \frac{{y}_{{kn}_{k , 1}} - {y}_{{kn}_{k , 2}}}{cos ( {\hat{φ}}_{{n}_{k , 1}}^{( prev )} ( - {\hat{\tilde{φ}}}_{k}^{( prev )} ) - cos ( {\hat{φ}}_{{n}_{k , 2}}^{( prev )} - {\hat{\tilde{φ}}}_{k}^{( prev )} )} , and \\ {\hat{e}}_{k} = {y}_{{kn}_{k , 1}} - {\hat{A}}_{k} cos ( {\hat{φ}}_{{n}_{k , 1}}^{( prev )} - {\hat{\tilde{φ}}}_{k}^{( prev )} )$$

with

$${n}_{k , 1} = {arg max}_{n ∈ \{ 1 , … , N \}} ( {y}_{kn} ) and {n}_{k , 2} = {arg min}_{n ∈ \{ 1 , … , N \}} ( {y}_{kn} ) .$$

Here, the controller 122 may determine two options for

$${\hat{φ}}_{k n}^{( next )}$$

within an interval [0, 2π], and the two closest options outside of [0, 2π]:

$${\hat{φ}}_{kn}^{( next , opt 1 )} = ( - arccos ( \frac{{y}_{kn} - {\hat{e}}_{k}}{{\hat{A}}_{k}} ) + {\hat{\tilde{φ}}}_{k}^{( prev )} ) mod 2 π \\ {\hat{φ}}_{kn}^{( next , opt 2 )} = ( + arccos ( \frac{{y}_{kn} - {\hat{e}}_{k}}{{\hat{A}}_{k}} ) + {\hat{\tilde{φ}}}_{k}^{( prev )} ) mod 2 π \\ {\hat{φ}}_{kn}^{( next , opt 3 )} = {max}_{opt 1 , opt 2} ( {\hat{φ}}_{kn}^{( next , opt 1 )} , {\hat{φ}}_{kn}^{( next , opt 2 )} ) - 2 π \\ {\hat{φ}}_{kn}^{( next , opt 4 )} = {min}_{opt 1 , opt 2} ( {\hat{φ}}_{kn}^{( next , opt 1 )} , {\hat{φ}}_{kn}^{( next , opt 2 )} ) + 2 π$$

where “mod” refers to a modulo operation. From these options, the controller 122 may determine an option that is closest to

$${\hat{φ}}_{n}^{( prev )} ,$$

and take the selected option as

$${\hat{φ}}_{kn}^{( next )} .$$

The controller 122 may then compute a weighted average:

$${\hat{φ}}_{n}^{( next )} = ( \frac{{\sum }_{k = 1}^{K} {\hat{φ}}_{kn}^{( next )} {c}_{kn}}{{\sum }_{k = 1}^{K} {c}_{kn}} ) mod 2 π \\ with weights {c}_{kn} = 1 - {( \frac{{y}_{kn} - {\hat{e}}_{k}}{{\hat{A}}_{k}} )}^{2}$$

The controller 122 may then determine two options for

$${\hat{\tilde{φ}}}_{kn}^{( next )}$$

within the interval [0, 2π], and the two closest options outside of [0, 2π]:

$${\hat{\tilde{φ}}}_{kn}^{( next , opt 1 )} = ( - arccos ( \frac{{y}_{kn} - {\hat{e}}_{k}}{{\hat{A}}_{k}} ) + {\hat{φ}}_{n}^{( next )} ) mod 2 π \\ {\hat{\tilde{φ}}}_{kn}^{( next , opt 2 )} = ( + arccos ( \frac{{y}_{kn} - {\hat{e}}_{k}}{{\hat{A}}_{k}} ) + {\hat{φ}}_{n}^{( next )} ) mod 2 π \\ {\hat{\tilde{φ}}}_{kn}^{( next , opt 3 )} = {max}_{opt 1 , opt 2} ( {\hat{\tilde{φ}}}_{kn}^{( next , opt 1 )} , {\hat{\tilde{φ}}}_{kn}^{( next , opt 2 )} ) - 2 π \\ {\hat{\tilde{φ}}}_{kn}^{( next , opt 4 )} = {min}_{opt 1 , opt 2} ( {\hat{\tilde{φ}}}_{kn}^{( next , opt 1 )} , {\hat{\tilde{φ}}}_{kn}^{( next , opt 2 )} ) + 2 π$$

From these options, the controller 122 may determine an option that is closest to

$${\hat{\tilde{φ}}}_{k}^{( prev )} ,$$

and take the selected option as

$${\hat{\tilde{φ}}}_{k n}^{( next )} .$$

The controller 122 may then compute a weighted average, using the same weights as noted above:

$${\hat{\tilde{φ}}}_{k}^{( next )} = ( \frac{{\sum }_{n = 1}^{N} {\hat{\tilde{φ}}}_{kn}^{( next )} {c}_{kn}}{{\sum }_{n = 1}^{N} {c}_{kn}} ) mod 2 π$$

In this way, the controller 122 may perform iterations so that the error in actual phases of the second phase shifter 114 and/or of the first phase shifter 106 is reduced.

As indicated above, FIGS. 1A-1E are provided as examples. Other examples may differ from what is described with regard to FIGS. 1A-1E. In general, the techniques and apparatuses described with respect to FIGS. 1A-1E can be used with any device that is capable of measuring Aₖ cos(φₙ−\tilde{φ}ₖ)+eₖ with at least two different phases \tilde{φ}ₖ of a second phase shifter 114 and unknown Aₖ and eₖ. For example, the techniques and apparatuses described herein can be used if two instances of the second phase shifter 114, configured to form an in-phase/quadrature (I/Q) measurement receiver, are provided with the same TX monitoring signal 160 to simultaneously measure the first measurement signals and the second measurement signals. Put another way, the techniques and apparatuses described herein can be applied to any apparatus that can measure a value proportional to cos(φ−\tilde{φ}ₖ) with at least two different \tilde{φ}ₖ.

Further, the number and arrangement of components shown in FIGS. 1A-1C are provided as an example. In practice, there may be additional components, fewer components, different components, or differently arranged components than those shown in FIGS. 1A-1C. Furthermore, two or more components shown in FIGS. 1A-1C may be implemented within a single component, or a single component shown in FIGS. 1A-1C may be implemented as multiple, distributed components. Additionally, or alternatively, a set of components (e.g., one or more components) shown in FIGS. 1A-1C may perform one or more functions described as being performed by another set of components shown in FIGS. 1A-1C.

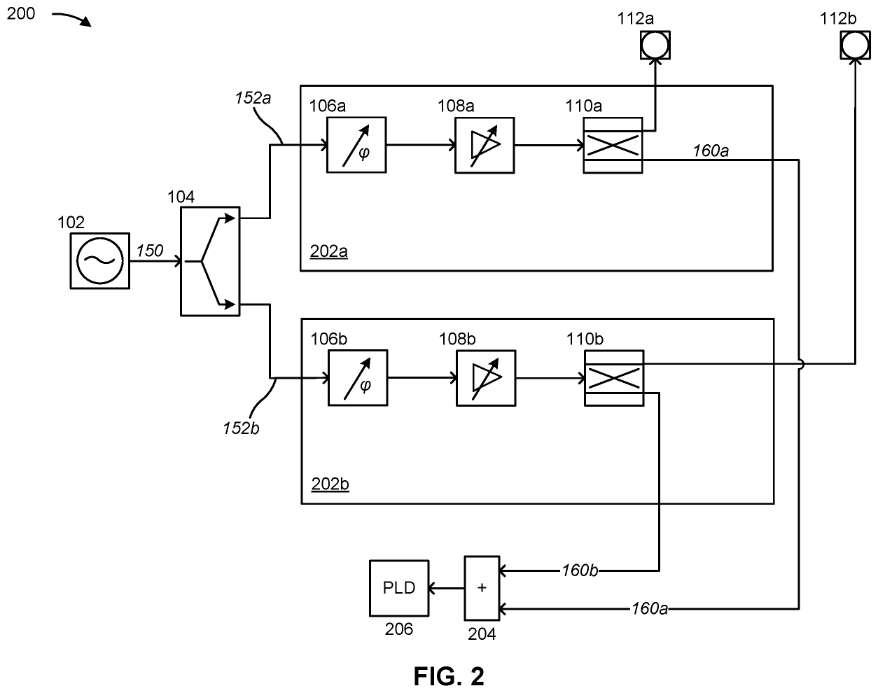

FIG. 2 is a diagram illustrating another example implementation of the device 100 capable of determining an actual phase of a phase shifter, as described herein. In the example implementation 200 of the device 100 shown in FIG. 2, the device 100 comprises a plurality of circuits 202 (e.g., circuits 202a and 202b, which may be integrated in a single MMIC), each associated with a respective one of a plurality of TX channels of the device 100. Here, each circuit 202 includes a respective phase shifter 106, a PA 108, and a coupler 110. Notably, a TX RF input signal 152 provided to each of the circuits 202 originates from the same LO 102 (e.g., from the LO signal 150 provided by the LO 102). As further shown, the device 100 may include a combiner 204 and a power level detector (PLD) 206.

In some implementations, a pair of TX channels of the device 100 are enabled at a given time, and TX monitoring signals 160 provided by the circuits 202 associated with the two enabled TX channels are added by the combiner 204. Here, a power of a signal resulting from this summation is measured by a power level detector (PLD) 206. A controller 122 (not shown in FIG. 2) can then determine actual phases of the phase shifters 106 of circuits 202 of the enabled TX channels. Thus, in such an implementation, a phase shifter 106 of a first of the two TX channels can be viewed as a TXPS, while the phase shifter 106 of the other of the two enabled TX channels can be viewed as a TPS.

In some implementations, in operation of the example implementation of the device 100 shown in FIG. 2, multiple TX channels are enabled (e.g., a first TX channel associated with circuit 202a and a second TX channel associated with circuit 202b), and multiple measurements at the PLD 206 are triggered with different combinations of phase settings in the phase shifter 106a of the first TX channel and the phase shifter 106b of the second TX channel.

In some implementations, a power measured by the PLD 206 can be derived by the following steps. First, an amplitude a and phase φₙ may be associated with an output of the phase shifter 106a to be characterized, and an amplitude ãₖ and phase \tilde{φ}ₖ may be associated with an output of the phase shifter 106b serving as the test phase shifter. Here, time signals at the outputs are vₙ(t)=a cos(ωt+φₙ) at the output of the phase shifter 106a to be characterized and \tilde{v}ₖ(t)=ãₖ cos(ωt+\tilde{φ}ₖ) at the output of the phase shifter 106b serving as the test phase shifter. Next, when summing the two signals and detecting the power of the resulting summed signal, power at the input of the PLD 206 is determined as:

$${P}_{kn} = \overline{{( {v}_{n} + {\tilde{v}}_{k} )}^{2}} = \frac{{a}^{2} + {\tilde{a}}_{k}^{2}}{2} + a {\tilde{a}}_{k} cos ( {φ}_{n} - {\tilde{φ}}_{k} ) ,$$

with

$$\overline{{( {v}_{n} + {\tilde{v}}_{k} )}^{2}}$$

being the timely average value of (vₙ+\tilde{v}ₖ)².
Next, the measurement values Pₖₙ can be processed in the manner described above with respect to FIGS. 1A-1E while interpreting Pₖₙ as

$${y}_{kn} , \frac{{a}^{2} + {\tilde{a}}_{k}^{2}}{2}$$

as eₖ, and (aãₖ) as Aₖ.

In some implementations, in the case of leakage of a signal from a TX channel that is not enabled, such leakage can be viewed as part of a signal provided by the phase shifter 106b serving as the test phase shifter, meaning that phases of the phase shifter 106a to be characterized can still be accurately determined. Here, when viewed as part of the resulting equivalent phase shifter 106b serving as the test phase shifter, these leakage signals distort the phase \tilde{φ}ₖ and amplitude ãₖ at the output of the equivalent phase shifter 106b serving as the test phase shifter. Because there are no constraints on the phase and amplitude of the phase shifter 106b serving as the test phase shifter in the algorithm described above, the phase of the phase shifter 106a to be characterized (TXPS) can still be determined accurately. In such a case, only the resulting phases for the equivalent phase shifter 106b serving as the test phase shifter need to be handled with caution, as these phases may not accurately represent the phases of the phase shifter 106b serving as the test phase shifter. One technique to address this issue is to disregard the resulting phases of the equivalent phase shifter 106b serving as the test phase shifter, and only use the results for the phase shifter 106a to be characterized for further evaluation.

In some implementations, all differential TX phases in a device 100 with at least two TX channels can be characterized. In one example, TX phases (e.g., actual phase shifts applied by phase shifters 106) of a device 100 in the form of an MMIC with four TX channels (e.g., TX1 through TX4) can be measured using the following procedure. First, a phase shifter 106 of a TX4 can be used as the phase shifter 106 serving as the test phase shifter and, one after the other, differential phase shifts associated with TX1, TX2, TX3 can be measured. Differential phase shifts of one TX after the other can be extracted in the manner described above (e.g., with the (TXPS, TPS) combinations (TX1, TX4), (TX2, TX4), (TX3, TX4)). Next, the phase shifter 106 of TX1 can be used as the phase shifter 106 serving as the test phase shifter, and, one after the other, differential phase shifts of TX2, TX3, TX4 can be measured. Differential phase shifts associated with one TX after the other can then be extracted in the manner described above (e.g., with (TXPS, TPS) combinations (TX2, TX1), (TX3, TX1), (TX4, TX1)). Here, since TX2 and TX3 are common to both of the measurements, either of TX2 or TX3 (or an average of both) can be used as a linking element to determine the differential phase shifts of TX1, TX2, TX3, and TX4. Notably, this procedure can be applied even when there is a non-negligible signal leakage through the TX instances that are not enabled.

In some implementations, all differential TX phases in a device 100 with two TX channels can be characterized. In one example, TX phases of a device 100 in the form of an MMIC with two TX channels (e.g., TX1 and TX2) can be measured. In some implementations, because there are only two different TX instances, there will be no leakage from other disabled TX instances. Thus, the algorithm described above can be used to determine the actual phase shifts associated with each of the two TX channels.

As indicated above, FIG. 2 is provided as an example. Other examples may differ from what is described with regard to FIG. 2. Further, the number and arrangement of components shown in FIG. 2 are provided as an example. In practice, there may be additional components, fewer components, different components, or differently arranged components than those shown in FIG. 2. Furthermore, two or more components shown in FIG. 2 may be implemented within a single component, or a single component shown in FIG. 2 may be implemented as multiple, distributed components. Additionally, or alternatively, a set of components (e.g., one or more components) shown in FIG. 2 may perform one or more functions described as being performed by another set of components shown in FIG. 2.

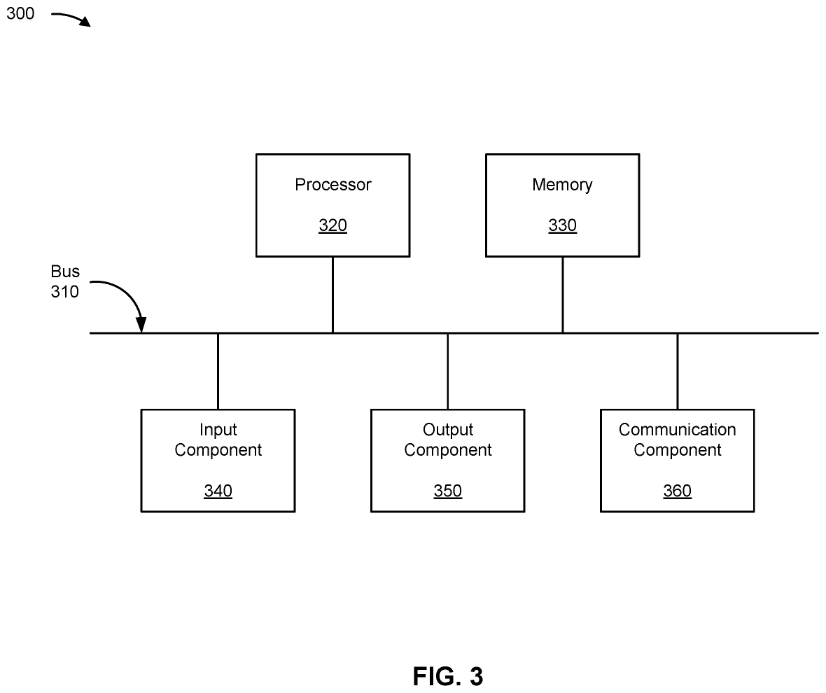

FIG. 3 is a diagram of example components of a device 300 associated with determination of an actual phase shift of a phase shifter. The device 300 may correspond to the controller 122. In some implementations, the controller 122 may include one or more components 300 and/or one or more components of the device 300. As shown in FIG. 3, the device 300 may include a bus 310, a processor 320, a memory 330, an input component 340, an output component 350, and/or a communication component 360.

The bus 310 may include one or more components that enable wired and/or wireless communication among the components of the device 300. The bus 310 may couple together two or more components of FIG. 3, such as via operative coupling, communicative coupling, electronic coupling, and/or electric coupling. For example, the bus 310 may include an electrical connection (e.g., a wire, a trace, and/or a lead) and/or a wireless bus. The processor 320 may include a central processing unit, a graphics processing unit, a microprocessor, a controller, a microcontroller, a digital signal processor, a field-programmable gate array, an application-specific integrated circuit, and/or another type of processing component. The processor 320 may be implemented in hardware, firmware, or a combination of hardware and software. In some implementations, the processor 320 may include one or more processors capable of being programmed to perform one or more operations or processes described elsewhere herein.

The memory 330 may include volatile and/or nonvolatile memory. For example, the memory 330 may include random access memory (RAM), read only memory (ROM), a hard disk drive, and/or another type of memory (e.g., a flash memory, a magnetic memory, and/or an optical memory). The memory 330 may include internal memory (e.g., RAM, ROM, or a hard disk drive) and/or removable memory (e.g., removable via a universal serial bus connection). The memory 330 may be a non-transitory computer-readable medium. The memory 330 may store information, one or more instructions, and/or software (e.g., one or more software applications) related to the operation of the device 300. In some implementations, the memory 330 may include one or more memories that are coupled (e.g., communicatively coupled) to one or more processors (e.g., processor 320), such as via the bus 310. Communicative coupling between a processor 320 and a memory 330 may enable the processor 320 to read and/or process information stored in the memory 330 and/or to store information in the memory 330.

The input component 340 may enable the device 300 to receive input, such as user input and/or sensed input. For example, the input component 340 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 350 may enable the device 300 to provide output, such as via a display, a speaker, and/or a light-emitting diode. The communication component 360 may enable the device 300 to communicate with other components via a wired connection and/or a wireless connection. For example, the communication component 360 may include a receiver, a transmitter, a transceiver, a modem, a network interface card, and/or an antenna.

The device 300 may perform one or more operations or processes described herein. For example, a non-transitory computer-readable medium (e.g., memory 330) may store a set of instructions (e.g., one or more instructions or code) for execution by the processor 320. The processor 320 may execute the set of instructions to perform one or more operations or processes described herein. In some implementations, execution of the set of instructions, by one or more processors 320, causes the one or more processors 320 and/or the device 300 to perform one or more operations or processes described herein. In some implementations, hardwired circuitry may be used instead of or in combination with the instructions to perform one or more operations or processes described herein. Additionally, or alternatively, the processor 320 may be configured to perform one or more operations or processes described herein. Thus, implementations described herein are not limited to any specific combination of hardware circuitry and software.

The number and arrangement of components shown in FIG. 3 are provided as an example. The device 300 may include additional components, fewer components, different components, or differently arranged components than those shown in FIG. 3. Additionally, or alternatively, a set of components (e.g., one or more components) of the device 300 may perform one or more functions described as being performed by another set of components of the device 300.

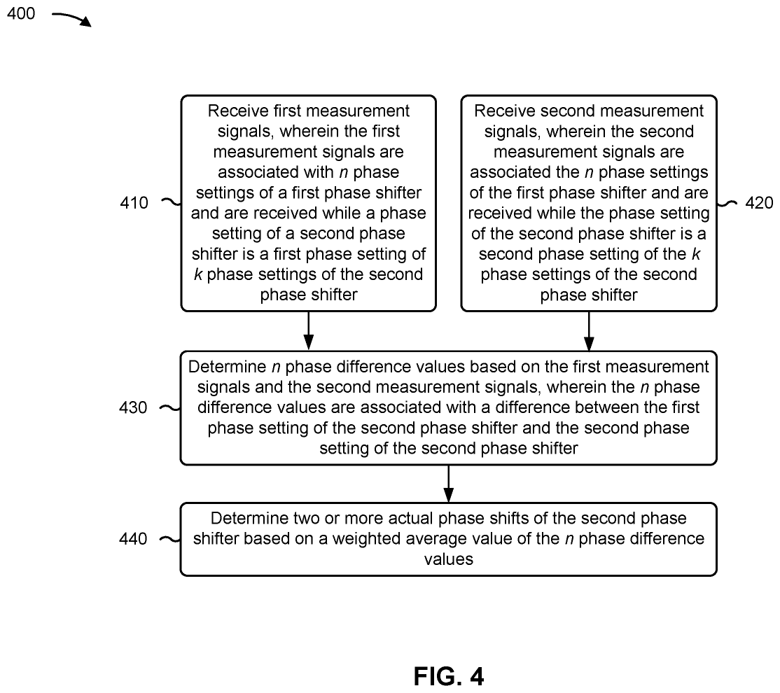

FIG. 4 is a flowchart of an example process 400 associated with determination of an actual phase shift of a phase shifter. In some implementations, one or more process blocks of FIG. 4 are performed by a controller (e.g., controller 122). Additionally, or alternatively, one or more process blocks of FIG. 4 may be performed by one or more components of device 300, such as processor 320, memory 330, input component 340, output component 350, and/or communication component 360.

As shown in FIG. 4, process 400 may include receiving first measurement signals, wherein the first measurement signals are associated with n phase settings of a first phase shifter, and wherein the first measurement signals are received while a phase setting of a second phase shifter is a first phase setting of k phase settings of the second phase shifter (block 410). For example, the controller may receive first measurement signals, wherein the first measurement signals are associated with n phase settings of a first phase shifter, and wherein the first measurement signals are received while a phase setting of a second phase shifter is a first phase setting of k phase settings of the second phase shifter, as described above.

As further shown in FIG. 4, process 400 may include receiving second measurement signals, wherein the second measurement signals are associated with the n phase settings of the first phase shifter, and wherein the second measurement signals are received while the phase setting of the second phase shifter is a second phase setting of the k phase settings of the second phase shifter (block 420). For example, the controller may receive second measurement signals, wherein the second measurement signals are associated with the n phase settings of the first phase shifter, and wherein the second measurement signals are received while the phase setting of the second phase shifter is a second phase setting of the k phase settings of the second phase shifter, as described above.

As further shown in FIG. 4, process 400 may include determining n phase difference values based on the first measurement signals and the second measurement signals, wherein the n phase difference values are associated with a difference between the first phase setting of the second phase shifter and the second phase setting of the second phase shifter (block 430). For example, the controller may determine n phase difference values based on the first measurement signals and the second measurement signals, wherein the n phase difference values are associated with a difference between the first phase setting of the second phase shifter and the second phase setting of the second phase shifter, as described above.

As further shown in FIG. 4, process 400 may include determining two or more actual phase shifts of the second phase shifter based on a weighted average value of the n phase difference values (block 440). For example, the controller may determine two or more actual phase shifts of the second phase shifter based on a weighted average value of the n phase difference values, as described above.

Process 400 may include additional implementations, such as any single implementation or any combination of implementations described below and/or in connection with one or more other processes described elsewhere herein.

In a first implementation, determining the n phase difference values comprises computing a first gain value and a first offset value based on the first measurement signals, determining a first phase difference signal based on the first gain value, the first offset value, and the first measurement signals, wherein the first phase difference signal is associated with differences between the n phase settings of the first phase shifter and the first phase setting of the second phase shifter, computing a second gain value and a second offset value based on the second measurement signals, determining a second phase difference signal based on the second gain value, the second offset value, and the second measurement signals, wherein the second phase difference signal is associated with differences between the n phase settings of the first phase shifter and the second phase setting of the second phase shifter, and determining the n phase difference values based on the first phase difference signal and the second phase difference signal.

In a second implementation, alone or in combination with the first implementation, determining the two or more actual phase shifts of the second phase shifter comprises determining k actual phase shifts of the second phase shifter, wherein each actual phase shift of the k actual phase shifts is associated with a respective phase setting of the k phase settings of the second phase shifter.

In a third implementation, alone or in combination with one or more of the first and second implementations, process 400 includes determining n actual phase shifts of the first phase shifter based on the k actual phase shifts of the second phase shifter, wherein each actual phase shift of the n actual phase shifts is associated with a respective phase setting of the n phase settings of the first phase shifter.

In a fourth implementation, alone or in combination with one or more of the first through third implementations, process 400 includes computing one or more updated gain values and one or more updated offset values associated with the second phase shifter, and determining two or more updated actual phase shifts of the second phase shifter based on the one or more updated gain values and the one or more updated offset values.

In a fifth implementation, alone or in combination with one or more of the first through fourth implementations, determining the two or more updated actual phase shifts comprises applying a weight value of zero to minimum and maximum values of the first measurement signals and to minimum and maximum values of the second measurement signals.

In a sixth implementation, alone or in combination with one or more of the first through fifth implementations, k is equal to two (k=2) and n is greater than or equal to five (n≥5).

In a seventh implementation, alone or in combination with one or more of the first through fifth implementations, k is greater than or equal to three (k≥3) and n is greater than or equal to four (n≥4).

In an eighth implementation, alone or in combination with one or more of the first through seventh implementations, the first measurement signals and the second measurement signals are digitized versions of DC components of results of mixing a transmit signal and a phase-shifted test signal, wherein the transmit signal and the phase-shifted test signal originate from the same LO.

In a ninth implementation, alone or in combination with one or more of the first through eighth implementations, the first measurement signals comprise a first set of n digital values, wherein each digital value in the first set of n digital values corresponds to a DC component of a result of mixing a first RF signal and a second RF signal while the first RF signal is phase-shifted by a respective phase setting of the n phase settings and the second phase shifter is set to the first phase setting of the k phase settings, and wherein the second measurement signals comprise a second set of n digital values, wherein each digital value in the second set of n digital values corresponds to a DC component of a result of mixing the first RF signal and the second RF signal while the first RF signal is phase-shifted by a respective phase setting of the n phase settings and the second phase shifter is set to the second phase setting of the k phase settings.

Although FIG. 4 shows example blocks of process 400, in some implementations, process 400 includes additional blocks, fewer blocks, different blocks, or differently arranged blocks than those depicted in FIG. 4. Additionally, or alternatively, two or more of the blocks of process 400 may be performed in parallel.

The following provides an overview of some Aspects of the present disclosure:

Aspect 1: A method, comprising: receiving first measurement signals, wherein the first measurement signals are associated with n phase settings of a first phase shifter, and wherein the first measurement signals are received while a phase setting of a second phase shifter is a first phase setting of k phase settings of the second phase shifter; receiving second measurement signals, wherein the second measurement signals are associated with the n phase settings of the first phase shifter, and wherein the second measurement signals are received while the phase setting of the second phase shifter is a second phase setting of the k phase settings of the second phase shifter; determining n phase difference values based on the first measurement signals and the second measurement signals, wherein the n phase difference values are associated with a difference between the first phase setting of the second phase shifter and the second phase setting of the second phase shifter; and determining two or more actual phase shifts of the second phase shifter based on a weighted average value of the n phase difference values.

Aspect 2: The method of Aspect 1, wherein determining the n phase difference values comprises: computing a first gain value and a first offset value based on the first measurement signals; determining a first phase difference signal based on the first gain value, the first offset value, and the first measurement signals, wherein the first phase difference signal is associated with differences between the n phase settings of the first phase shifter and the first phase setting of the second phase shifter; computing a second gain value and a second offset value based on the second measurement signals; determining a second phase difference signal based on the second gain value, the second offset value, and the second measurement signals, wherein the second phase difference signal is associated with differences between the n phase settings of the first phase shifter and the second phase setting of the second phase shifter; and determining the n phase difference values based on the first phase difference signal and the second phase difference signal.

Aspect 3: The method of any of Aspects 1-2, wherein determining the two or more actual phase shifts of the second phase shifter comprises determining k actual phase shifts of the second phase shifter, wherein each actual phase shift of the k actual phase shifts of the second phase shifter is associated with a respective phase setting of the k phase settings of the second phase shifter.

Aspect 4: The method of Aspect 3, further comprising determining n actual phase shifts of the first phase shifter based on the k actual phase shifts of the second phase shifter, wherein each actual phase shift of the n actual phase shifts of the first phase shifter is associated with a respective phase setting of the n phase settings of the first phase shifter.

Aspect 5: The method of any of Aspects 1-4, further comprising: computing one or more updated gain values and one or more updated offset values associated with the second phase shifter; and determining two or more updated actual phase shifts of the second phase shifter based on the one or more updated gain values and the one or more updated offset values.

Aspect 6: The method of Aspect 5, wherein determining the two or more updated actual phase shifts comprises applying a weight value of zero to minimum and maximum values of the first measurement signals and to minimum and maximum values of the second measurement signals.

Aspect 7: The method of any of Aspects 1-6, wherein k is equal to two (k=2) and n is greater than or equal to five (n≥5).

Aspect 8: The method of any of Aspects 1-6, wherein k is greater than or equal to three (k≥3) and n is greater than or equal to four (n≥4).

Aspect 9: The method of any of Aspects 1-8, wherein the first measurement signals and the second measurement signals are digitized versions of direct current (DC) components of results of mixing a transmit signal and a phase-shifted test signal, wherein the transmit signal and the phase-shifted test signal originate from the same local oscillator (LO).

Aspect 10: The method of any of Aspects 1-9, wherein the first measurement signals comprises a first set of n digital values, wherein each digital value in the first set of n digital values corresponds to a direct current (DC) component of a result of mixing a first RF signal and a second RF signal while the first RF signal is phase-shifted by a respective phase setting of the n phase settings and the second phase shifter is set to the first phase setting of the k phase settings of the second phase shifter, and wherein the second measurement signals comprises a second set of n digital values, wherein each digital value in the second set of n digital values corresponds to a DC component of a result of mixing the first RF signal and the second RF signal while the first RF signal is phase-shifted by a respective phase setting of the n phase settings and the second phase shifter is set to the second phase setting of the k phase settings of the second phase shifter.

Aspect 11: A device, comprising: a set of components comprising a first phase shifter and a second phase shifter, the set of components being configured to: provide first measurement signals, wherein the first measurement signals are associated with n phase settings of the first phase shifter, and wherein the first measurement signals are provided while a phase setting of a second phase shifter is at a first phase setting of k phase settings of the second phase shifter; provide second measurement signals, wherein the second measurement signals are associated with the n phase settings of the first phase shifter, and wherein the second measurement signals are provided while the phase setting of the second phase shifter is at a second phase setting of the k phase settings of the second phase shifter; and a controller configured to: receive the first measurement signals; receive the second measurement signals; determine n phase difference values based on the first measurement signals and the second measurement signals, wherein the n phase difference values are associated with a difference between the first phase setting of the second phase shifter and the second phase setting of the second phase shifter; and determine two or more actual phase shifts of the second phase shifter based on the n phase difference values.

Aspect 12: The device of Aspect 11, wherein the controller, to determine the n phase difference values, is configured to: compute a first gain value and a first offset value based on the first measurement signals; determine first phase difference signal based on the first gain value, the first offset value, and the first measurement signals, wherein the first phase difference signal is associated with differences between the n phase settings of the first phase shifter and the first phase setting of the second phase shifter; compute a second gain value and a second offset value based on the second measurement signals; determine second phase difference signal based on the second gain value, the second offset value, and the second measurement signals, wherein the second phase difference signal is associated with differences between the n phase settings of the first phase shifter and the second phase setting of the second phase shifter; and determine the n phase difference values based on the first phase difference signal and the second phase difference signal.

Aspect 13: The device of any of Aspects 11-12, wherein the controller, to determine the two or more actual phase shifts, is configured to determine k actual phase shifts of the second phase shifter, wherein each actual phase shift of the k actual phase shifts is associated with a respective phase setting of the k phase settings of the second phase shifter.

Aspect 14: The device of Aspect 13, wherein the controller is further configured to determine n actual phase shifts of the first phase shifter based on the k actual phase shifts of the second phase shifter, wherein each actual phase shift of the n actual phase shifts is associated with a respective phase setting of the n phase settings of the first phase shifter.

Aspect 15: The device of any of Aspects 11-14, wherein the controller is further configured to: compute one or more updated gain values and one or more updated offset values associated with the second phase shifter; and determine two or more updated actual phase shifts of the second phase shifter based on the one or more updated gain values and the one or more updated offset values.

Aspect 16: The device of Aspect 15, wherein the controller, to determine the one or more updated actual phase shifts, is configured to apply a weight value of zero to minimum and maximum values of the first measurement signals and to minimum and maximum values of the second measurement signals.

Aspect 17: The device of any of Aspects 11-16, wherein the first measurement signals and the second measurement signals are digitized versions of direct current (DC) components of results of mixing a transmit signal and a phase-shifted test signal, wherein the transmit signal and the phase-shifted test signal originate from the same local oscillator (LO).

Aspect 18: A device, comprising: a local oscillator (LO) configured to provide an LO signal; a transmit phase shifter (TXPS) configured to phase shift transmit signals according to n phase settings of the TXPS, wherein the transmit signals are based on the LO signal; a test phase shifter (TPS) configured to phase shift test signals according to k phase settings of the TPS, wherein the test signals are based on the LO signal; a mixer configured to generate mixed signals based on the transmit signals and the test signals; an analog to digital converter (ADC) configured to digitize the mixed signals to generate measurement signals; and a controller configured to: determine n phase difference values based on the measurement signals, wherein the n phase difference values are associated with a difference between a first phase setting of the k phase settings of the TPS and a second phase setting of the k phase settings of the TPS; and determine two or more actual phase shifts of the TPS based on the n phase difference values.

Aspect 19: The device of Aspect 18, wherein the controller, to determine the n phase difference values, is configured to: compute gain values and offset values based on the measurement signals; determine phase difference signals based on the gain values, the offset values, and the measurement signals, wherein a phase difference signal is associated with differences between the n phase settings of the TXPS and a corresponding phase setting of the k phase settings of the TPS; and determine the n phase difference values based on the phase difference signals.

Aspect 20: The device of any of Aspects 18-19, wherein the controller, to determine the two or more actual phase shifts, is configured to determine k actual phase shifts of the TPS, wherein each actual phase shift of the k actual phase shifts is associated with a respective phase setting of the k phase settings of the TPS.

Aspect 21: A system configured to perform one or more operations recited in one or more of Aspects 1-20.

Aspect 22: An apparatus comprising means for performing one or more operations recited in one or more of Aspects 1-20.

Aspect 23: A non-transitory computer-readable medium storing a set of instructions, the set of instructions comprising one or more instructions that, when executed by a device, cause the device to perform one or more operations recited in one or more of Aspects 1-20.

Aspect 24: A computer program product comprising instructions or code for executing one or more operations recited in one or more of Aspects 1-20.

The foregoing disclosure provides illustration and description, but is not intended to be exhaustive or to limit the implementations to the precise forms disclosed. Modifications and variations may be made in light of the above disclosure or may be acquired from practice of the implementations.

As used herein, the term “component” is intended to be broadly construed as hardware, firmware, and/or a combination of hardware and software. It will be apparent that systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.” No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items,), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method, comprising:
receiving first measurement signals,
wherein the first measurement signals are associated with n phase settings of a first phase shifter, and
wherein the first measurement signals are received while a phase setting of a second phase shifter is a first phase setting of k phase settings of the second phase shifter;
receiving second measurement signals,
wherein the second measurement signals are associated with the n phase settings of the first phase shifter, and
wherein the second measurement signals are received while the phase setting of the second phase shifter is a second phase setting of the k phase settings of the second phase shifter;
determining n phase difference values based on the first measurement signals and the second measurement signals,
wherein the n phase difference values are associated with a difference between the first phase setting of the second phase shifter and the second phase setting of the second phase shifter; and
determining two or more actual phase shifts of the second phase shifter based on a weighted average value of the n phase difference values.

2. The method of claim 1, wherein determining the n phase difference values comprises:
computing a first gain value and a first offset value based on the first measurement signals;
determining a first phase difference signal based on the first gain value, the first offset value, and the first measurement signals,
wherein the first phase difference signal is associated with differences between the n phase settings of the first phase shifter and the first phase setting of the second phase shifter;
computing a second gain value and a second offset value based on the second measurement signals;
determining a second phase difference signal based on the second gain value, the second offset value, and the second measurement signals,
wherein the second phase difference signal is associated with differences between the n phase settings of the first phase shifter and the second phase setting of the second phase shifter; and
determining the n phase difference values based on the first phase difference signal and the second phase difference signal.

3. The method of claim 1, wherein determining the two or more actual phase shifts of the second phase shifter comprises determining k actual phase shifts of the second phase shifter, wherein each actual phase shift of the k actual phase shifts is associated with a respective phase setting of the k phase settings of the second phase shifter.

4. The method of claim 3, further comprising determining n actual phase shifts of the first phase shifter based on the k actual phase shifts of the second phase shifter, wherein each actual phase shift of the n actual phase shifts is associated with a respective phase setting of the n phase settings of the first phase shifter.

5. The method of claim 1, further comprising:
computing one or more updated gain values and one or more updated offset values associated with the second phase shifter; and
determining two or more updated actual phase shifts of the second phase shifter based on the one or more updated gain values and the one or more updated offset values.

6. The method of claim 5, wherein determining the two or more updated actual phase shifts comprises applying a weight value of zero to minimum and maximum values of the first measurement signals and to minimum and maximum values of the second measurement signals.

7. The method of claim 1, wherein k is equal to two (k=2) and n is greater than or equal to five (n≥5).

8. The method of claim 1, wherein k is greater than or equal to three (k≥3) and n is greater than or equal to four (n≥4).

9. The method of claim 1, wherein the first measurement signals and the second measurement signals are digitized versions of direct current (DC) components of results of mixing a transmit signal and a phase-shifted test signal, wherein the transmit signal and the phase-shifted test signal originate from the same local oscillator (LO).

10. The method of claim 1, wherein the first measurement signals comprise a first set of n digital values, wherein each digital value in the first set of n digital values corresponds to a direct current (DC) component of a result of mixing a first RF signal and a second RF signal while the first RF signal is phase-shifted by a respective phase setting of the n phase settings and the second phase shifter is set to the first phase setting of the k phase settings, and wherein the second measurement signals comprise a second set of n digital values, wherein each digital value in the second set of n digital values corresponds to a DC component of a result of mixing the first RF signal and the second RF signal while the first RF signal is phase-shifted by a respective phase setting of the n phase settings and the second phase shifter is set to the second phase setting of the k phase settings.

11. A device, comprising:
a set of components comprising a first phase shifter and a second phase shifter, the set of components being configured to:
provide first measurement signals,
wherein the first measurement signals are associated with n phase settings of the first phase shifter, and
wherein the first measurement signals are provided while a phase setting of a second phase shifter is at a first phase setting of k phase settings of the second phase shifter;
provide second measurement signals,
wherein the second measurement signals are associated with the n phase settings of the first phase shifter, and
wherein the second measurement signals are provided while the phase setting of the second phase shifter is at a second phase setting of the k phase settings of the second phase shifter; and
a controller configured to:
receive the first measurement signals;
receive the second measurement signals;
determine n phase difference values based on the first measurement signals and the second measurement signals,
wherein the n phase difference values are associated with a difference between the first phase setting of the second phase shifter and the second phase setting of the second phase shifter; and
determine two or more actual phase shifts of the second phase shifter based on the n phase difference values.

12. The device of claim 11, wherein the controller, to determine the n phase difference values, is configured to:
compute a first gain value and a first offset value based on the first measurement signals;
determine first phase difference signal based on the first gain value, the first offset value, and the first measurement signals,
wherein the first phase difference signal is associated with differences between the n phase settings of the first phase shifter and the first phase setting of the second phase shifter;
compute a second gain value and a second offset value based on the second measurement signals;
determine second phase difference signal based on the second gain value, the second offset value, and the second measurement signals,
wherein the second phase difference signal is associated with differences between the n phase settings of the first phase shifter and the second phase setting of the second phase shifter; and
determine the n phase difference values based on the first phase difference signal and the second phase difference signal.

13. The device of claim 11, wherein the controller, to determine the two or more actual phase shifts, is configured to determine k actual phase shifts of the second phase shifter, wherein each actual phase shift of the k actual phase shifts is associated with a respective phase setting of the k phase settings of the second phase shifter.

14. The device of claim 13, wherein the controller is further configured to determine n actual phase shifts of the first phase shifter based on the k actual phase shifts of the second phase shifter, wherein each actual phase shift of the n actual phase shifts is associated with a respective phase setting of the n phase settings of the first phase shifter.

15. The device of claim 11, wherein the controller is further configured to:
compute one or more updated gain values and one or more updated offset values associated with the second phase shifter; and
determine two or more updated actual phase shifts of the second phase shifter based on the one or more updated gain values and the one or more updated offset values.

16. The device of claim 15, wherein the controller, to determine the one or more updated actual phase shifts, is configured to apply a weight value of zero to minimum and maximum values of the first measurement signals and to minimum and maximum values of the second measurement signals.

17. The device of claim 11, wherein the first measurement signals and the second measurement signals are digitized versions of direct current (DC) components of results of mixing a transmit signal and a phase-shifted test signal, wherein the transmit signal and the phase-shifted test signal originate from the same local oscillator (LO).

18. A device, comprising:
a local oscillator (LO) configured to provide an LO signal;
a transmit phase shifter (TXPS) configured to phase shift transmit signals according to n phase settings of the TXPS, wherein the transmit signals are based on the LO signal;
a test phase shifter (TPS) configured to phase shift test signals according to k phase settings of the TPS, wherein the test signals are based on the LO signal;
a mixer configured to generate mixed signals based on the transmit signals and the test signals;
an analog to digital converter (ADC) configured to digitize the mixed signals to generate measurement signals; and
a controller configured to:
determine n phase difference values based on the measurement signals, wherein the n phase difference values are associated with a difference between a first phase setting of the k phase settings of the TPS and a second phase setting of the k phase settings of the TPS; and
determine two or more actual phase shifts of the TPS based on the n phase difference values.

19. The device of claim 18, wherein the controller, to determine the n phase difference values, is configured to:
compute gain values and offset values based on the measurement signals;
determine phase difference signals based on the gain values, the offset values, and the measurement signals,
wherein a phase difference signal is associated with differences between the n phase settings of the TXPS and a corresponding phase setting of the k phase settings of the TPS; and
determine the n phase difference values based on the phase difference signals.

20. The device of claim 18, wherein the controller, to determine the two or more actual phase shifts, is configured to determine k actual phase shifts of the TPS, wherein each actual phase shift of the k actual phase shifts is associated with a respective phase setting of the k phase settings of the TPS.
